(19) United States
(12) Patent Application Publication
(10) Pub. No.: US 2021/0020405 A1
(43) Pub. Date: Jan. 21, 2021

(54) EQUIPMENT AND METHODS FOR PLASMA PROCESSING

(71) Applicant: Tokyo Electron Limited, Tokyo (JP)

(72) Inventors: Peter Ventzek, Austin, TX (US); Mitsunori Ohata, Miyagi (JP); Alok Ranjan, Austin, TX (US)

(21) Appl. No.: 16/515,513

(22) Filed: Jul. 18, 2019

(51) Int. Cl. H01J 37/32; H01L 21/3213; C23C 16/455

(52) U.S. Cl. CPC H01J 37/321; H01L 21/32136; C23C 16/45544; H01J 2237/3341; H01J 37/32091; H01J 2237/3321; C23C 16/45536

(57) ABSTRACT

In one embodiment, a plasma processing apparatus includes a plasma processing chamber that includes a first portion and a second portion. The first portion includes sidewalls and a top cover having a through hole. The second portion is coupled to the first portion via the through hole. A substrate holder is disposed in the first portion of the plasma processing chamber. A first coil is disposed over the first portion and a second coil is disposed over the first portion and around the second portion.

### TECHNICAL FIELD

The present invention relates generally to plasma processing, and, in particular embodiments, to equipment and methods for plasma processing.

### BACKGROUND

Generally, semiconductor devices used in electronics, such as mobile phones, digital cameras, computers etc., are fabricated by sequentially depositing layers of dielectric, conductive, and semiconductor materials over a semiconductor substrate, and patterning the various layers (including portions of the substrate) to form structures that function as circuit components (e.g., transistors, resistors, and capacitors) and as interconnect elements, such as conductive lines and vertical connectors (e.g., contacts and vias). Patterned masks are also used to introduce impurities (e.g., dopants) into selected regions of the semiconductor substrate or other material layers to tailor the electrical properties of the regions exposed to the impurities. Using innovations such as immersion lithography and multiple patterning, the semiconductor industry has continually miniaturized dimensions in patterned layers to increase the packing density of components, thereby reducing the cost of electronics. Further reductions in device footprint has been achieved with three-dimensional structures, for example, a fin field-effect transistor (FinFET) wherein the gate electrode wraps around three sides of closely-spaced, narrow and long fin-shaped semiconductor features formed by etching trenches into the semiconductor substrate.

Continued shrinking of minimum feature sizes to a few nanometers in device and device isolation geometries intensifies the challenges in semiconductor fabrication technology. There arises an increasing demand for etching techniques to form, for example, lines, pillars, sidewalls, trenches, and holes, having high aspect ratios and near-vertical walls, along with an increasing demand for deposition techniques capable of conformal deposition for advanced memory and logic technologies, and void-free gap-fill of the high aspect ratio trenches and holes with small openings. Some of the processing techniques available to form the requisite structures employ plasma processing technology. Examples of plasma-assisted processing utilized to create the microstructures in forming, connecting, and isolating electronic components in semiconductor devices include reactive ion etching (RIE), alternating deposition and etch cycles (e.g., the Bosch process), high density plasma chemical vapor deposition (HDP-CVD), plasma-enhanced atomic layer etch (PEALE), and plasma-enhanced atomic layer deposition (PEALD). Successful deployment of plasma deposition and etch technology in the manufacturing of semiconductor devices with critical dimensions in the nanometer regime entails meeting stringent requirements of process uniformity across a wide (e.g., 300 mm) wafer, not only with precisely controlled dimensions (e.g., linewidths, etch depth, and film thicknesses), but also with precise control often at atomic scale dimensions of process features such as etch profile, conformality, deposition and etch selectivity, and anisotropy. In addition to the technical challenges in providing advanced process capability with advanced process control, there are cost constraints to be considered during plasma equipment design, for example, wafer throughput, equipment configurability, and equipment cost. Overcoming the hurdles in providing plasma processing technology for manufacturing scaled semiconductor devices is a challenge that requires further innovations in plasma equipment design.

### SUMMARY

In accordance with an embodiment, a plasma processing apparatus includes a plasma processing chamber comprising a first portion and a second portion. The first portion comprises sidewalls and a top cover comprising a through hole. The second portion is coupled to the first portion via the through hole. A substrate holder is disposed in the first portion of the plasma processing chamber. A first coil is disposed over the first portion and a second coil is disposed over the first portion and around the second portion.

In accordance with another embodiment, a plasma processing apparatus comprises a plasma processing chamber that comprises a first portion and a second portion, which are formed as a monolithic structure. The first portion is configured to sustain a first plasma, which is configured to provide a first ion flux and a first radical flux at a substrate. The second portion is configured to sustain a second plasma, which is configured to provide a second ion flux and a second radical flux at the substrate. A first ratio between the first ion flux and the first radical flux is greater than a second ratio between the second ion flux and the second radical flux. A substrate holder is disposed in the first portion of the plasma processing chamber.

In accordance with another embodiment, a method of plasma processing comprises sustaining a first plasma within a first portion of a plasma processing chamber, sustaining a second plasma within a second portion of a plasma processing chamber, and processing a substrate with the first plasma and the second plasma. The first plasma provides a first ion flux and a first radical flux at the substrate, while the second plasma provides a second ion flux and a second radical flux at the substrate. A first ratio between the first ion flux and the first radical flux is greater than a second ratio between the second ion flux and the second radical flux.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A illustrates a cross-sectional view of a plasma processing apparatus in accordance with an embodiment of the invention;

FIG. 1B illustrates a top-view of the plasma processing apparatus illustrated in FIG. 1A;

FIG. 1C illustrates a cross-sectional view of a plasma processing apparatus in accordance with an alternative embodiment of the invention;

FIG. 2A illustrates a cross-sectional view of the plasma processing apparatus illustrated in FIG. 1A, wherein the first portion is configured to generate a first plasma sustained by inductively coupled RF power applied to the first coil, and the second portion is configured to generate a second plasma sustained by inductively coupled RF power applied to the second coil, in accordance with an embodiment of the invention;

FIG. 2B illustrates a top-view of the plasma processing apparatus illustrated in FIG. 1B, wherein the plasma processing chamber is configured to generate the first plasma and the second plasma, as illustrated in FIG. 2A;

FIG. 3A illustrates a cross-sectional view of the plasma processing apparatus illustrated in FIG. 1A, wherein the first portion is configured to generate a first plasma sustained by capacitively coupled RF power applied to the first coil, and the second portion is configured to generate a second plasma sustained by inductively coupled RF power applied to the second coil, in accordance with an embodiment of the invention;

FIG. 3B illustrates a top-view of the plasma processing apparatus illustrated in FIG. 1B, wherein the plasma processing chamber is configured to generate the first plasma and the second plasma, as illustrated in FIG. 3A;

FIG. 4 illustrates the variation in ion to radical ratio at the surface of a substrate placed in the plasma apparatus with a process parameter in accordance with various embodiments of the present invention;

FIG. 5A illustrates a cross-sectional view of a plasma processing apparatus comprising an integrated coil in accordance with another embodiment of the invention;

FIG. 5B illustrates a top-view of the plasma processing apparatus illustrated in FIG. 5A;

FIG. 5C illustrates a cross-sectional view of a plasma processing apparatus comprising an integrated coil in accordance with an alternative embodiment of the invention;

FIG. 5D illustrates a schematic representation of a plasma processing system in accordance with an alternative embodiment of the present invention;

FIGS. 6A-6F illustrate different operating modes of a plasma processing apparatus discussed in FIGS. 5A-5D in accordance with embodiments of the present invention;

FIG. 7A illustrates a cross-sectional view of a plasma processing chamber having two portions, wherein a grounded staggered bilayer conductive grid is placed in a region between the first portion and the second portion of the plasma processing chamber, and wherein the RF power and ground taps of the coils (not shown) are configured to generate a plasma only in the second portion of the plasma generator, in accordance with an embodiment of the invention;

FIG. 7B illustrates a cross-sectional view of the same plasma processing chamber as illustrated in FIG. 7A, wherein a grounded high-aspect-ratio conductive grid is placed in a region between the first portion and the second portion of the plasma processing chamber, in accordance with an alternative embodiment of the invention;

FIG. 8 illustrates a system-level implementation of dynamic reconfiguration of the plasma processing apparatus as discussed in various embodiments;

FIG. 9A illustrates a schematic of one processing cycle of a dual-step cyclic-etch process in accordance with an embodiment of the invention; and

FIG. 9B illustrates a schematic of one processing cycle comprising a two-cycle atomic-layer etch-deposition combination process in accordance with an embodiment of the invention.

### DETAILED DESCRIPTION OF ILLUSTRATIVE EMBODIMENTS

The present invention relates generally to plasma processing apparatus and methods suitable for semiconductor device fabrication, and, in particular embodiments, to apparatus and methods of generating plasma sources to provide a controlled ratio of ion flux to radical flux at the surface of a substrate being processed, the ratio being variable over a wide range of values.

Conventional coil based plasma sources can operate in a mixed capacitive and inductive mode (referred to as ICP-mode). However, at a fixed operating frequency, the relative degree of capacitive and inductive coupling is not adjustable, although the capacitive coupling may be effectively blocked/reduced by inserting a Faraday shield (e.g., a metal sheet) between the coil and the plasma chamber. The conventional plasma sources may also be operated as resonators in either purely inductive (referred to as PI-mode) or purely capacitive mode (referred to as PC-mode), but are not capable of making a transition between the two modes during operation. In the PI-mode, resonators may generate a plasma that is an excellent source of radicals. Resonators may also generate a plasma that is a significant source of ions, particularly when the plasma source is in the PC-mode. There are many potential applications for a radical rich plasma and, likewise, for an ion rich plasma. In addition, it may be advantageous to make a transition (e.g., from ion rich to radical rich plasma) smoothly during the processing.

Embodiments of the present application disclose a plasma processing apparatus that is able to achieve a fast and smooth transition during operation from an ion rich plasma to a radical rich plasma using configurable plasma apparatus and methods that will be described in detail below.

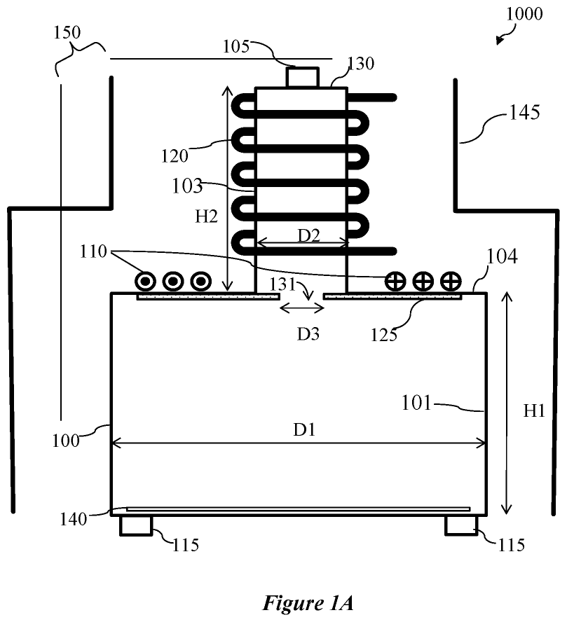

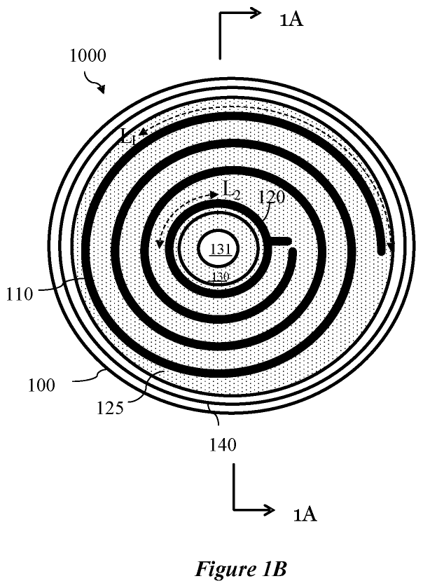

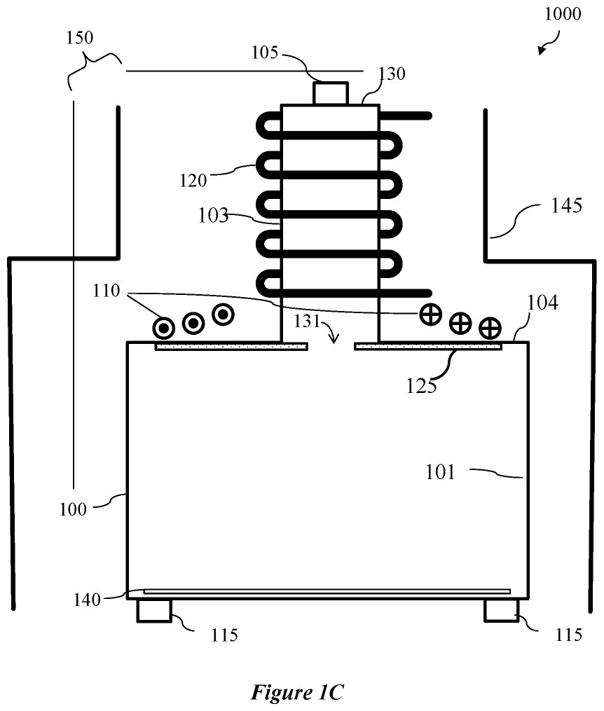

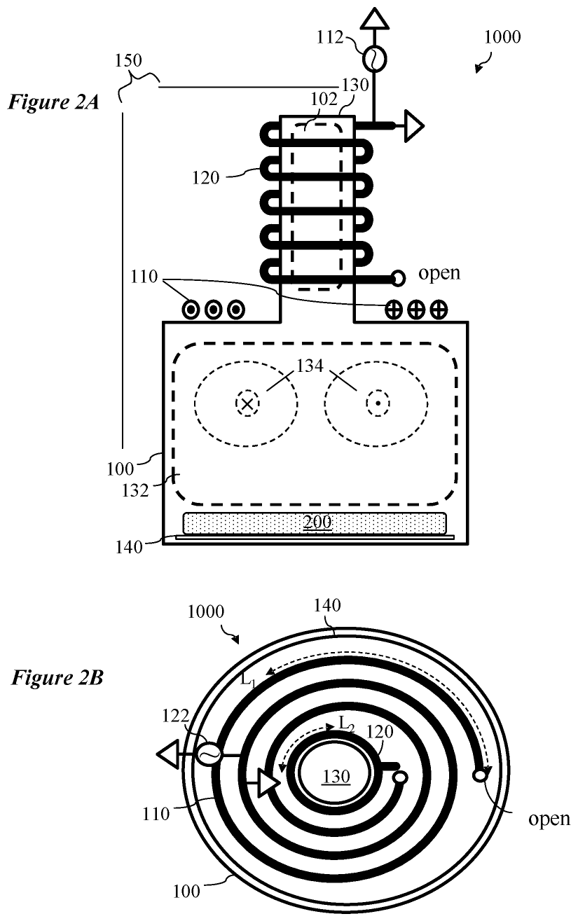

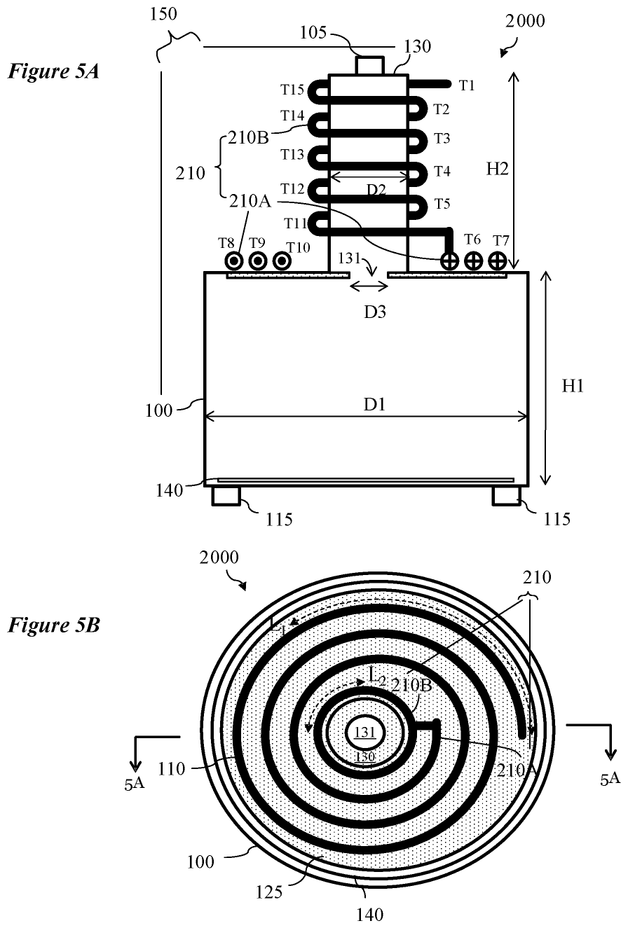

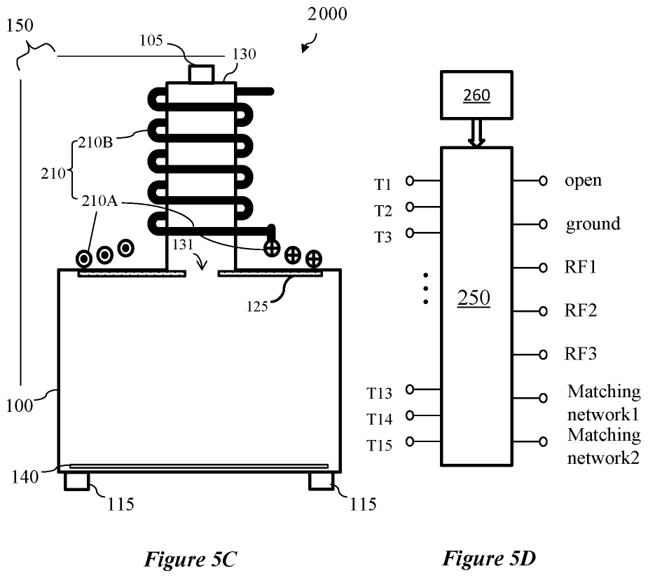

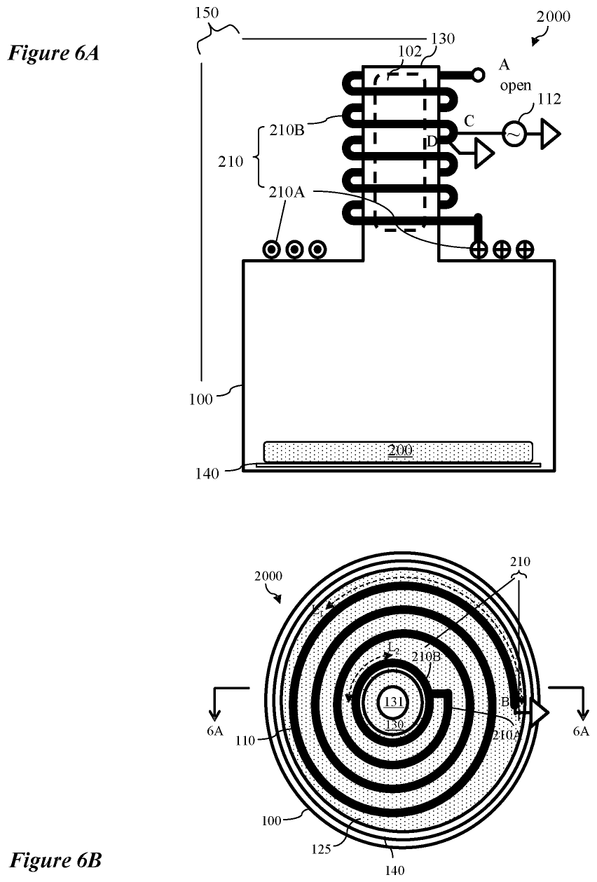

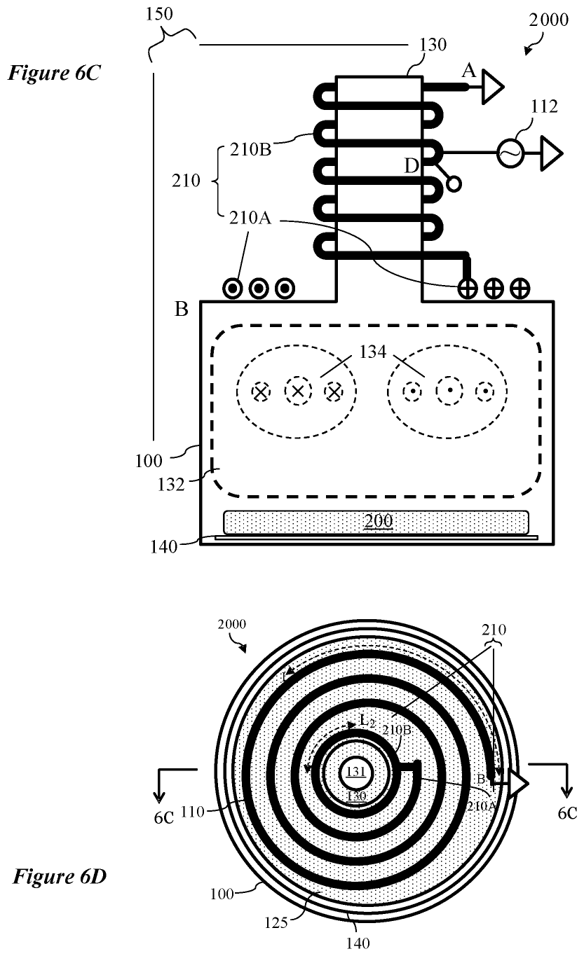

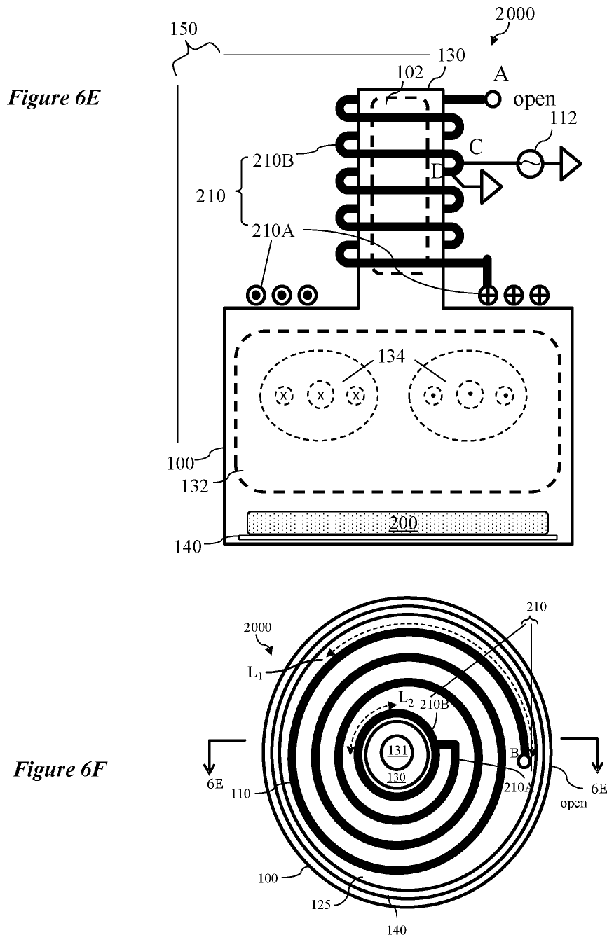

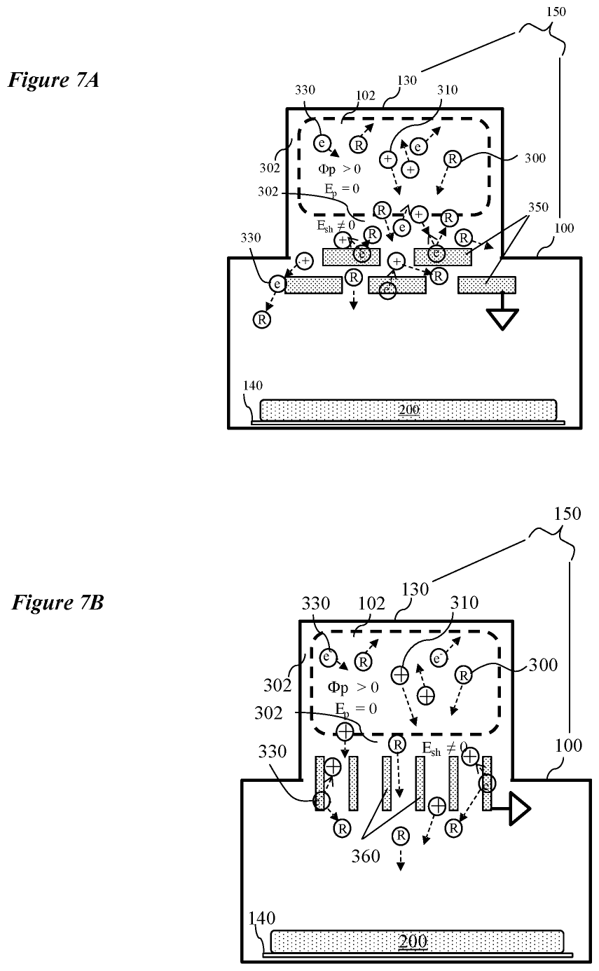

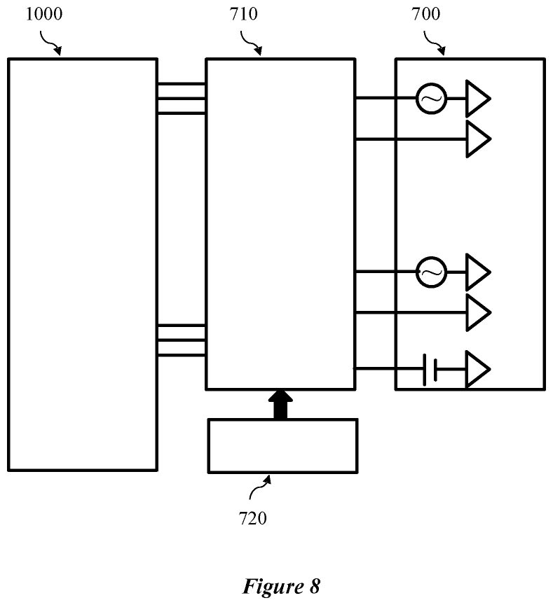

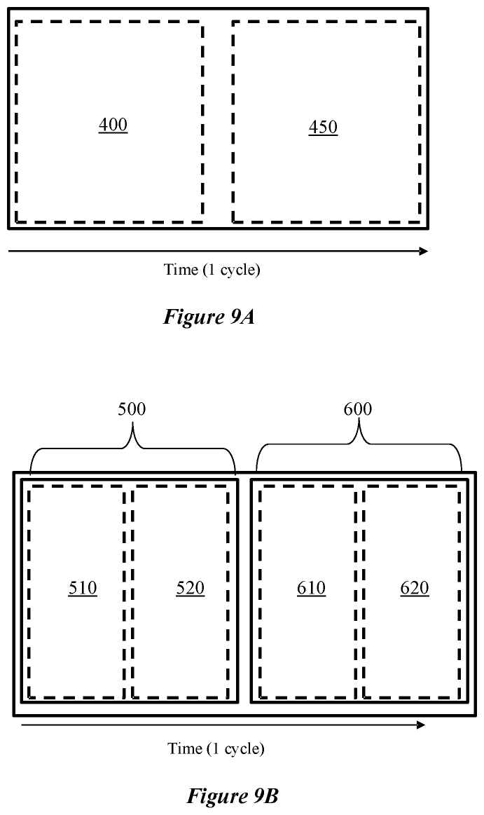

An embodiment of the plasma processing apparatus will first be described using FIG. 1. Operating modes of the plasma processing apparatus will be explained using FIGS. 2, 3, and 4. An alternative embodiment of the plasma processing apparatus will then be described using FIG. 5 followed by description of its operation in FIG. 6. An embodiment structural component to improve the ion to radical flux ratio will be described using FIG. 7. A system level schematic of the plasma processing system comprising the plasma processing apparatus will be described using FIG. 8. Representative process cycles using the plasma processing apparatus will be described using FIG. 9.

FIGS. 1A and 1B illustrate a cross-sectional view and a top-view of an embodiment of a plasma processing apparatus 1000 in accordance with an embodiment of the present invention.

As illustrated in FIG. 1A, the plasma processing chamber 150 includes two portions: a lower first portion 100 and an upper second portion 130 disposed over the first portion 100 so as to form a single monolithic structure.

The sidewalls 101 of the first portion 100 may be made of a conductive material such as stainless steel or aluminum coated with a film such as yttria (e.g., YₓO_{y} or YₓO_{y}F_{z}), or a film consistent with the process (e.g., carbon or silicon), or as known to a person skilled in the art. The first portion 100 may further include a top cover 104 that substantially encloses the first portion. At least a portion of the top cover 104 includes a window 125 made of a dielectric material such as quartz. The window 125 may be circular in one embodiment.

The upper second portion 130 is narrower than the lower first portion 100 and in one embodiment is placed symmetrically along a central axis of the plasma processing chamber 150. In particular, the window 125 has a through-hole 131 for connecting the first portion 100 to the second portion 130.

The sidewalls 103 of the second portion 130 are made of a dielectric material such as quartz. In various embodiments, the sidewalls of the second portion 130 comprising quartz may be bonded together to the window 125. In addition, the first portion 100 and the second portion 130 may be housed within an enclosure 145, which may be a Faraday cage or a solid enclosure.

A gas input system 105, illustrated over the top of the second portion 130 in FIG. 1A, provides process gases into the plasma processing chamber 150. The gas input system 105 may include multiple inputs and may input different gases into the plasma processing chamber 150 through inlets at different locations, for example, at the sidewalls 101. The gases in the plasma processing chamber 150 may flow between the first portion 100 and the second portion 130 through the through-hole 131. A representative gas outlet 115 is illustrated at the bottom of the plasma processing chamber 150. The various inlets and exhausts used for carrier, reactant, or purge gases, as well as any electrodes and electrical connections inside the plasma processing chamber 150 are not shown and would be known to a person having ordinary skill in the art.

Referring to FIG. 1B, in one embodiment, the first portion 100 and the second portion 130 are shaped as two vertically stacked hollow cylinders connected by the circular through-hole 131. As illustrated in FIGS. 1A and 1B, the first portion 100 has a first diameter D1 and a first height H1, and the second portion 130 has a second diameter D2 and a second height H2. The through-hole 131 may comprise a single opening in the dielectric window 125, or comprise a plurality of orifices, each having a small diameter. The region across which the through-hole extends has a third diameter D3 which is less than the second diameter D2.

The plasma processing apparatus 1000 comprises two coils, a first coil 110 and a second coil 120, with multiple taps providing electrical connections to RF power sources and ground (the reference potential). Each coil may be electrically configured independently and connected to a separate RF power source.

Referring to FIG. 1A, the first coil 110 is coupled to the plasma to be formed in the first portion 100 through the window 125. Similarly, the second coil 120 is coupled to the plasma to be formed in the second portion 130 through the sidewalls comprising a dielectric material such as quartz.

In one embodiment, the first coil 110 is a planar conductive spiral, and is disposed over the top surface the first portion 100, outside the upper second portion 130, as illustrated in FIGS. 1A and 1B. In one embodiment, the second coil 120 is formed as a vertical coil, e.g., shaped as a cylindrical helix and is disposed around a vertical column of the second portion 130 of the plasma processing chamber 150.

In the example illustrated in FIGS. 1A and 1B, a disc-shaped substrate holder 140 is disposed close to the base of the first portion 100. The substrate holder 140 may be configured to hold the wafer during processing. The first coil 110 may be designed relative to the substrate holder 140 as known to a person skilled in the art, for example, to minimize across wafer variation.

The flexibility of electrically configuring two coils independently allows the plasma processing apparatus 1000 to be configured in various combinations of modes. In one embodiment, the first coil 110 may be a first resonator, e.g., a planar resonator and the second coil 120 may be a second resonator, e.g., a helical resonator. Each resonator may be independently configured to operate in the PI-mode or the PC-mode at its respective resonance frequency. In some other embodiment, both the first and the second coils 110 and 120 may be included in the same resonator circuit. Alternatively, the first coil 110 and/or the second coil 120 may be operated in the non-resonant ICP-mode. Using different combinations of modes, it is possible to sustain a pair of plasma discharges with widely different plasma properties in two interconnected portions (first portion 100 and second portion 130) of the monolithic plasma processing chamber 150, advantageously expanding the process space for plasma processing used in manufacturing semiconductor devices.

The wire-length, L, of a resonator is determined by the desired operating frequency, f. Resonance occurs only when wire length L matches a resonance criterion based on the wavelength λ of an electromagnetic wave in the resonator at the operating frequency f selected at the RF power source coupled to the resonator, as discussed further below. As known to persons skilled in the art, wavelength λ depends not only on the operating frequency f but also on the dielectric constants and thicknesses of the materials adjacent to the wire such as the dielectric window 125 and any insulation around the metal conductor. A constraint on the wire-length L imposes corresponding restrictions on the first diameter D1 of the first portion 100, the second diameter D2 and the second height H2 of the second portion 130. In a design where the first and the second coils 110 and 120 are operated at resonance, these dimensions of the plasma processing chamber 150 are related to each other, as explained further below. Such constraints imposed by the resonance criterion are not applicable in the ICP-mode where a coil is not operated at resonance. However, a matching network may need to be added for efficient coupling of RF power from the RF power source to the coil.

Referring again to FIGS. 1A and 1B, first diameter D1 of the first portion 100 has to be large enough to accommodate the substrate holder 140. In addition, the number of turns N₁ and the first length L₁ of the first coil 110 depend on second diameter D2 of the second portion 130, and the width ((D1−D2)/2) of the ring-shaped region of the top cover 104 outside the second portion 130. Accordingly, a constraint on the first length L₁ imposes a corresponding constraint on the relative values of the first and second diameters D1 and D2 (for a given pitch of the spiral wire of a planar first coil 110). For example, for a half-wavelength (λ/2) resonator operated at f=27.12 MHz, the first length L₁ is about 4 m (λ is about 8 m). This corresponds to about five turns of an exemplary spiral coil having an average diameter of about 250 mm. Five turns of a spiral using a typical resonator wire, e.g., a wire of width D_{W} about 8 mm wound at a pitch P_{W} of about 16 mm, can be accommodated within a concentric ring about 100 mm wide. Accordingly, the difference between the first and the second diameters (D1−D2) is 200 mm and, if the first diameter D1 is selected to be 400 mm, given that a standard silicon wafer used in high volume manufacturing is 300 mm in diameter, then the second diameter D2 is 200 mm In this example, the ratio of the first diameter to the second diameter (D1:D2) is 2:1. In various embodiments, the ratio of the first diameter to the second diameter (D1:D2) may range from about 5:1 to about 4:3. From the range of the ratio of the first diameter to the second diameter (D1:D2), it is expected that the second diameter D2 may vary from about 75 mm to about 200 mm, in accordance with some embodiments. A smaller diameter may be used as long as a laminar gas flow can be maintained during processing.

In the example embodiment in FIG. 1A, if the second coil 120 is also operated as a resonator then its second length L₂ is also defined by the respective resonance criterion. The number of turns N₂ of the second coil 120 (assuming a helix) is roughly L₂/(πD₂) and also, roughly H2/P_{W} because the second portion 130 has a height H2≈(N₂×P_{W}) to accommodate N₂ turns of the helix at a coil pitch P_{W}. Accordingly, the second length L₂ for resonance and the pitch P_{W} of the second coil 120 that is helically wound roughly define the area (D2×H2) of the second portion 130 of the plasma processing chamber 150: (D₂×H₂)≈(L₂×P_{W})/π. For example, if both the first and second coils 110 and 120 in FIG. 1A are λ/2 resonators and use the same frequency f=27.12 MHz, then first length L₁ would be equal to the second length L₂ and may be 4 m. Using the coil pitch P_{W} to equal 16 mm as illustration, the product of the second diameter and the second height (D2×H2) is roughly 2.04×10⁴ mm² and, since the second diameter D2 is about 200 mm, the second height H2 is roughly 204 mm. For a fixed frequency f, the wavelength λ and, hence, the second length L₂ of a resonator remain constant. Then, as explained above, the product of the second diameter and the second height (D2×H2) may change roughly proportional to the coil pitch P_{W}. The coil pitch P_{W} may vary from about 10 mm to about 20 mm in various embodiments. Consequently, the second height H2 of the second portion 130 is also related to the second diameter D2. Accordingly, the variation in the second diameter D2 (described above) would result in a corresponding change in second height H2, in accordance with the constraints imposed by the resonance criterion.

As known to a person skilled in the art, the coil lengths (e.g., first length L₁ and second length L₂) are roughly inversely proportional to the operating frequency f because the velocity of the electromagnetic wave in the coil given by the product (fλ) remains constant. The choice of the operating frequency f would, thus, alter the dimensions of the plasma processing chamber 150.

The first height H1 of the first portion 100 of the plasma processing chamber 150 may vary from about 100 mm to about 200 mm depending on the space allocated for the plasma and for additional hardware placed between the second portion 130 and the substrate holder 140, for example, an ion filter or neutralizing grid, described further below.

In various embodiments, the first coil 110 and the second coil 120 may be designed to function together in the same electrical circuit (e.g., the same resonant circuit). In some embodiments, both the coils (first coil 110 and second coil 120) are resonators. Then their lengths (first length L₁ and second length L₂) are multiples of λ/4, where the even multiples may be electrically configured as λ/4 or as λ/2 resonators. At the RF frequencies in accordance with one or more embodiments, λ is a few meters (e.g. λ=4 m in the example embodiment described above with reference to FIGS. 1A and 1B). In embodiments where the first coil 110 and the second coil 120 are driven by RF sources at the same operating frequency f, the ratio of the first and the second lengths (L₁ and L₂) is roughly either 1:1 or 1:2. If either coil is operated in the ICP-mode (not at resonance), then the ratio may vary from about 1:1 to about 1:5, with the shorter length corresponding to the coil operating in the non-resonant ICP-mode.

In alternate embodiments, the first coil 110 may be shaped similar to a partial conical helix, as illustrated in FIG. 1C. Although embodiments of the present application are being described in a two portion (first portion 100 and second portion 130) design, other modifications such a multi-portion design can be similarly implemented in accordance with alternate embodiments of the present invention. In particular, multiple second portions 130 may be implemented in accordance with alternate embodiments of the present invention.

The structure of the plasma processing apparatus 1000, described with reference to FIGS. 1A, 1B, and 1C, resembles that of a top-hat; hence may be referred to as a top-hat dual resonator.

Although components of the example embodiments illustrated in FIGS. 1A, 1B, and 1C are described to have specific geometrical shapes and symmetric placements, it is understood that these shapes and symmetric placements are for illustrative purposes only; other embodiments may have other shapes and/or asymmetric placements.

As further described below, the plasma processing apparatus 1000 may be configured to vary the ion-to-radical ratio γ.

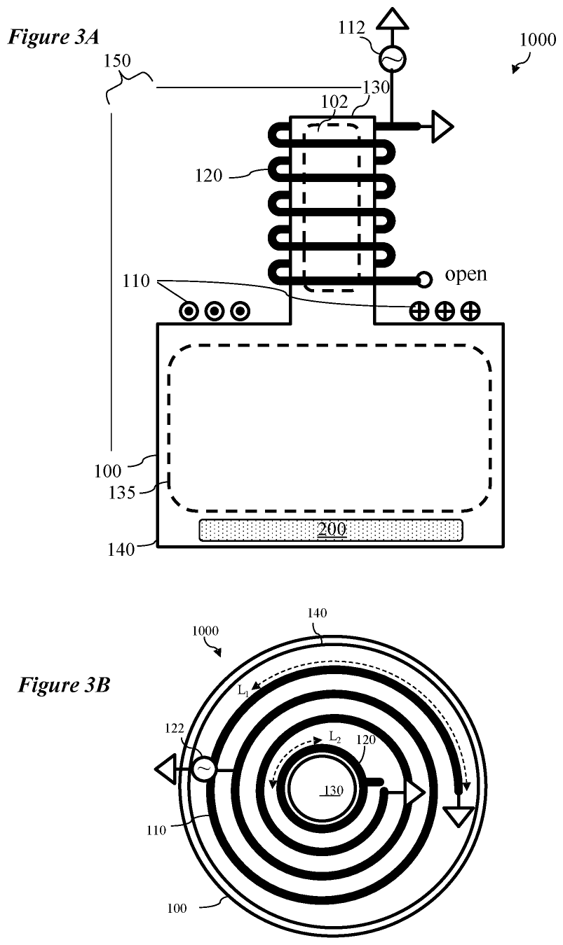

The different operation modes of the plasma processing apparatus discussed in various embodiments of the invention will be now described using FIGS. 2A and 2B and alternately using FIGS. 3A and 3B. In these illustrations and subsequent figures, for clarity, the window 125 shown in FIGS. 1A and 1C is not further illustrated. However it is to be understood that a window is always present between the first coil 110 and the plasma in the first portion 100.

As known to a person having ordinary skill in the art, while most of the naturally occurring plasma is thermally generated at very high temperatures, plasma in semiconductor processing equipment may be triggered or ignited by electrical discharge through a gas. Once ignited, the plasma state is sustained by a high frequency RF power source coupled inductively or capacitively to the plasma, in different embodiments.

Referring to FIGS. 2A and 2B, the first coil 110 is configured in the PI-mode to couple RF power inductively to sustain an inductively-coupled plasma 132. In contrast, in the embodiment of FIGS. 3A and 3B, the first coil 110 is configured in the PC-mode to couple RF power capacitively to sustain a capacitively-coupled plasma 135, as described in greater detail below. The inductively-coupled plasma 132 and the capacitively-coupled plasma 135, being in proximity of a substrate 200 placed on the substrate holder 140, may be considered to be direct plasmas in contact with the substrate being processed, as illustrated in FIGS. 2A and 3A. The second plasma 102 (in the second portion 130 of the plasma processing chamber 150), being separated from the substrate 200 by a distance of about the height of the first portion 100, may be considered to be an indirect plasma.

FIG. 2A illustrates the electrical configuration in the PI-mode of the second coil 120 (electrical connections to the first coil 110 are not shown). FIG. 2B illustrates the electrical configuration of the first coil 110 which is also operating in the PI-mode.

In FIG. 2A, one end of the vertical second coil 120 is connected to ground (indicated by a solid arrow) and an opposite end is open circuit (indicated by a solid circle). A helical coil connected in this manner is a quarter-wavelength resonator exhibiting electrical resonance at a frequency corresponding to the length of the coil, L₂, being equal to one-fourth of a wavelength, λ, or, L₂=λ/4. At resonance a standing wave is formed wherein, at the grounded end, the current is at a maximum and the voltage is zero, and the current is zero. At the open end, the voltage is at a maximum and the current is zero. The voltage and current are 90° out of phase. An RF power source, referred to as the first RF power source 112, is connected to the second coil 120 at a tap location close to the ground end of the second coil 120. The second plasma 102 is sustained by inductively coupling the RF power in the second coil 120 to the second plasma 102 in the second portion 130 of the plasma processing chamber 150. The RF power may be applied, for example, at 27 MHz.

FIG. 2B illustrates the planar first coil electrically configured in the PI-mode to generate inductively-coupled plasma 132 (see FIG. 2A) in the first portion 100 of the plasma processing chamber 150. Two ends of the first coil 110 are open circuit, and a ground connection is made at the center of the coil (equidistant from the two ends). This configuration is that of a half-wavelength resonator exhibiting electrical resonance at a frequency corresponding to the length of the coil, L₁, being equal to one-half of a wavelength, λ, or, L₁=λ/2. At resonance, a standing wave is formed wherein, at the two open ends, the voltage is at a maximum and the current is zero. At the ground connection in the center, the current is at a maximum and the voltage is zero. The voltage and current are 90° out of phase. An RF power source (independent of the first RF power source 112), referred to as the second RF power source 122, is connected to the first coil 110. Typically, for inductive coupling between the first coil 110 and the inductively-coupled plasma 132, the location of the RF tap is chosen close to the ground connection at the center of the first coil 110.

Referring again to FIG. 2A, the RF oscillations in the first coil 110 may sustain the inductively-coupled plasma 132 in the first portion 100 of the plasma processing chamber 150. The ion and free electron densities are highest roughly in the toroid region 134 of the inductively-coupled plasma 132, indicated by two dashed ellipses in FIG. 2A. Corresponding to the high density of mobile charged particles, there are high current oscillations (indicated by dashed circles in FIG. 2A) induced in the toroid region 134. As indicated in FIG. 2A, the oscillating induced-current in the inductively-coupled plasma 132 is nearly 180° out of phase with the oscillating current in the first coil 110. For example, at an instant when the coil-current is flowing counterclockwise the plasma-current is flowing clockwise, as indicated by the arrowheads (crosses and dots) in FIG. 2A.

In an alternate method of operation, FIGS. 3A and 3B illustrate a different half-wavelength resonator configuration for the first coil 110 while no change is made to the PI-mode connections for the second coil 120. In this configuration, the first coil 110 is in the PC-mode. Two ends of the first coil 110 are connected to ground and the second RF power source 122 is connected to a center tap (equidistant from the two ends), as illustrated in FIG. 3B. The corresponding stationary wave pattern at resonance is such that the current is at a maximum and the voltage is zero at the two ends of first coil 110 that are connected to ground. At the RF tap located half-way between the two ends, the voltage is at its maximum and the current in the coil is negligible. In accordance with one embodiment, the resonators in FIGS. 2B and 3B are both λ/2 resonators and resonate at the same wavelength λ and frequency f. In both the configurations the resonant voltage and current are 90° out of phase. The difference is that the resonant current in the coil at the ground connections is smaller with the PC-mode configuration in FIG. 3B relative to the PI-mode configuration in FIG. 2B. In the PC-mode configuration the wire length between the RF tap and ground taps is much greater compared to the PI-mode configuration for inductive coupling, illustrated in FIG. 2B. Accordingly, the magnitude of the maximum current is lower. One consequence of a low maximum RF current is that instead of inductive coupling to the ignited plasma, the RF power in the planar first coil 110 gets coupled capacitively to sustain a capacitively-coupled plasma 135. As a person skilled in the art can appreciate, characteristics of the inductively-coupled plasma 132 and the capacitively-coupled plasma 135 are different.

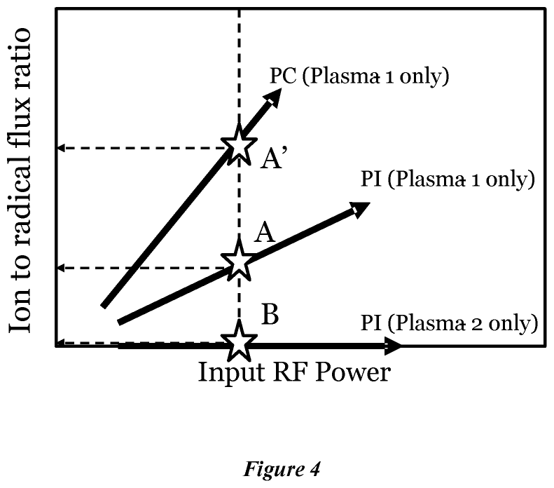

FIG. 4 illustrates the response of the ion-to-radical ratio to the input RF power for the plasma processing apparatus discussed in various embodiments of the invention.

The ion-to-radical ratio is the ratio of the flux of ions (Γᵢ) to the flux of radicals (Γᵣ) at the surface of a substrate being processed in the plasma processing chamber 150. The upper two solid arrows labeled “(Plasma-1 only)” represents the configurations wherein the second plasma 102 in the second portion 130 of the plasma processing chamber 150 has been extinguished by removing (not powering) the first RF power source 112. Among the two curves labeled “(Plasma-1 only),” the curve labeled “PI” refers to the first coil 110 being configured in the PI-mode to be inductively coupled to sustain an inductively-coupled plasma 132 (see e.g., FIGS. 2A and 2B), and the curve labeled “PC” refers to the first coil 110 being configured in the PC-mode to be capacitively coupled to sustain the capacitively-coupled plasma 135 (see e.g., FIGS. 3A and 3B).

As illustrated schematically in FIG. 4, if only the plasma in the first portion 100 were used for processing then, for a given input RF power, the substrate may be exposed either to plasma with a low ion-to-radical ratio (high radical flux) or to plasma with a high ion-to-radical ratio (high ion flux) by configuring the plasma processing apparatus 1000 to operate either at the operating point labeled A or at the operating point labeled A′. The plasma processing apparatus 1000 may be switched relatively quickly between the two operating points A and A′ by switching between alternative configurations of ground and RF taps, for example, by mechanical or solid-state switches operated using, for example, an electronic controller along with servo motors.

However, using only the above, the ability to decouple the radical flux, from the ion flux is limited. The flexibility to control the radical flux, may be enhanced if the radical flux could be modulated independently from the ion flux. The addition of a second portion 130 to the plasma processing chamber 150 of the plasma processing apparatus 1000 provides the additional flexibility of increasing the radical flux while roughly maintaining the same ion flux by using radicals extracted from the second plasma 102. This is illustrated by the curve labeled “(Plasma-2 only)” in FIG. 4, corresponding to the configuration wherein only the second plasma 102 in the second portion 130 of the plasma processing chamber 150 has been generated by connecting the first RF power source 112 and removing the second RF power source 122.

In further embodiments, the net flux from the second portion 130 to the first portion 100 may be engineered to roughly entirely comprise neutral particles by using a neutralizing grid disposed between the second portion 130 and the first portion 100 of the plasma processing chamber 150. Several example embodiments of plasma processing chambers 150 including the grid are described in greater detail below. Selective extraction of radicals from the second plasma 102 allows the plasma processing apparatus 1000 to be configured to operate on the curve labeled “(Plasma-2 only)” in FIG. 4, where it is shown that the ion-to-radical ratio is roughly equal to zero at any input RF power.

Accordingly in various embodiments, the plasma processing apparatus 1000 may be reconfigured relatively quickly from an operating point A or A′ to the operating point B using switching hardware similar to that described above in the context of switching between operating points A and A′. It is understood that by using both the second RF power source 122 and first RF power source 112 and both the first and second coils 110 and 120, it may be possible to dynamically switch the plasma processing apparatus 1000 between operating points, thereby varying the ion-to-radical ratio over a wide range of values.

FIGS. 5A, 5B, 5C, and 5D illustrate a plasma processing apparatus 2000 in accordance with an alternative embodiment of the present invention.

This embodiment is similar to the plasma processing apparatus 1000 described above with reference to FIGS. 1A, 1B, and 1C, with the exception that the planar first coil 110 and the vertical second coil 120 of the plasma processing apparatus 1000 (see FIGS. 1A, 1B, and 1C) are physically connected in the plasma processing apparatus 2000 to form one monolithic or integrated coil 210 having a planar first portion 210A and a vertical second portion 210B, in accordance with another embodiment of the invention. In one embodiment, the first coil 110 and the second coil 120 are part of a single monolithic wire. In another embodiment, the first coil 110 and the second coil 120 are bonded together as an integrated structure. FIGS. 5A and 5B illustrate a cross-sectional view and a top-view of the plasma processing apparatus using the integrated coil 210. In FIG. 5C the first portion 210A of the integrated coil 210 is shaped similar to a partial conical helix. The first portion 210A and the second portion 210B of the integrated coil 210 may be physically bonded together or, alternatively, may be formed from the same monolithic wire.

In addition, for illustration, a plurality of taps T1-T15 (shown in FIG. 5A) may be used to connect the coil to power and ground. Some of the plurality of taps (e.g., T1-T7) may be configured to receive power while the remaining ones of the plurality of taps (e.g., T8-T15) may be configured to receive ground. Accordingly, any subset of the plurality of taps T1-T15 may be activated electrically (or mechanically) using a switching matrix that can re-configure the taps to change the operation mode of the plasma processing apparatus 2000 during a plasma process cycle or even during a plasma process step.

Although described in various embodiments as achieving resonance, using the plurality of taps T1-T15 to power the plasma processing chamber 150, some embodiments may operate in a mixed mode by inserting appropriate matching networks using an addressable switching matrix 250 configured by a programmable electronic controller 260, as illustrated in the schematic representation of a plasma processing system in FIG. 5D. In FIG. 5D, the taps T1-T15 are connected to separate terminals shown on the left side of the switching matrix 250. The taps T4-T12 are not shown explicitly connected to respective terminals of the switching matrix 250. Instead, these connections are indicated implicitly by the ellipsis between T3 and T13. Other terminals of the switching matrix 250 (shown on the right side) are either open-circuit or connected to ground, or an RF-source, or an impedance matching network, in accordance with the states of addressable switches inside the switching matrix 250. The switching matrix 250 may be configured to a desired state by a set of control signals from a programmable electronic controller 260 shown connected to a data bus at the top of the switching matrix.

FIGS. 6A-6F illustrate three different operating modes of a plasma processing apparatus 2000 (described in FIGS. 5A-5D) using three different configurations of RF power and ground taps. The two end-taps of the integrated coil 210 are first end-tap A and second end-tap B, located in the planar first portion 210A and the vertical second portion 201B, respectively. An RF power source may be connected at RF power third tap-C, located at a length λ/4 from the first end-tap A. A fourth tap D located a little further from first end-tap A, close to the RF power third tap C, may be used as a ground tap. The cross-sectional views (FIGS. 6A, 6C, 6E) illustrate the first, second, fourth taps A, C, and D in the vertical second portion 201B and the top-views (FIGS. 6B, 6D, 6F) illustrate the second end-tap B in the planar portion of the integrated coil 210.

FIGS. 6A and 6B illustrate the first operating mode of the plasma processing apparatus 2000 wherein the RF power and ground taps are configured to sustain a second plasma 102 in the second portion 130 of the plasma processing chamber 150 by inductive coupling between the second plasma 102 and the vertical second portion 201B of the integrated coil 210, while no plasma is generated in the first portion 100 of the plasma processing chamber 150. The cross-sectional view of the plasma processing apparatus 2000 in FIG. 6A illustrates that the first end-tap A is an open-circuit. The first RF power source 112 is connected at the third tap C, and the fourth tap D is connected to ground, which configures the portion of the integrated coil 210 between first and fourth taps A and D to operate as a λ/4 resonator in the PI-mode. In this same configuration of the integrated coil 210, the top-view of the plasma processing apparatus 2000 in FIG. 6B illustrates that the second end-tap B of the planar first portion 210A is connected to ground. Grounding both the second and the fourth taps B and D with no RF power source in between prevents any plasma discharge in the first portion 100 of the plasma processing chamber 150.

FIGS. 6C and 6D illustrate the second operating mode of the plasma processing apparatus 2000 wherein the RF power and ground taps are configured to sustain an inductively-coupled plasma 132 in the first portion 100 of the plasma processing chamber 150 by inductive coupling between the inductively-coupled plasma 132 and the planar first portion 210A of the integrated coil 210, while no plasma is generated in the second portion 130 of the plasma processing chamber 150. The cross-sectional view of the plasma processing apparatus 2000 in FIG. 6C illustrates that the first end-tap A is grounded. The first RF power source 112 is connected at the third tap C but the fourth tap D is open circuit in this configuration of the integrated coil 210. In this same configuration, the top-view of the plasma processing apparatus 2000 in FIG. 6D illustrates that the second end-tap B of the planar first portion 210A is connected to ground.

FIGS. 6E and 6F illustrates the third operating mode of the plasma processing apparatus 2000 wherein the RF power and ground taps are configured to sustain an inductively-coupled plasma 132 in the first portion 100 of the plasma processing chamber 150 by inductive coupling between the first plasma (i.e., inductively-coupled plasma 132) and the planar first portion 210A of the integrated coil 210, and generate the second plasma 102 in the second portion 130 of the plasma processing chamber 150 by inductive coupling between the second plasma 102 and the vertical second portion 210B of the integrated coil 210. The cross-sectional view of the plasma processing apparatus 2000 in FIG. 6E illustrates that the first end-tap A is an open-circuit. The first RF power source 112 is connected at the third tap C, and the fourth tap D is connected to ground, same as done for the first operating mode (see FIG. 6A). However, as illustrated in the top-view of the plasma processing apparatus 2000 in FIG. 6D, for the third operating mode the second end-tap B of the planar first portion 210A is kept open. Removing the ground connection at the second end-tap B allows RF power driven by the first RF power source 112 to couple to the inductively-coupled plasma 132 in the first portion 100 of the plasma processing chamber 150.

FIGS. 7A and 7B illustrate embodiments of the plasma processing chamber 150 wherein a conductive grid is placed in a region between the first portion 100 and the second portion 130 of the plasma processing chamber.

The configuration used in the embodiments used for illustration in FIGS. 7A and 7B sustains second plasma 102 in the second portion 130 while no plasma is generated in the first portion 100. Second plasma 102 comprises neutral radicals 300, positively charged ions 310, and free electrons 330, as illustrated in FIGS. 7A and 7B. A flux of particles in the second portion 130 towards the conductive grid is indicated by dashed arrows. In FIG. 7A, a staggered bilayer conductive grid 350 and, in FIG. 7B, a high-aspect-ratio conductive grid 360 are shown connected to ground. The bulk second plasma 102 indicated by the dashed rectangle in FIGS. 7A and 7B is roughly charge neutral, having about an equal number of positively charged ions and negatively charged electrons. There is negligible electric field (Eₚ) inside the bulk plasma while the electric potential (Φₚ) is a constant. However, a thin region around the bulk second plasma 102, referred to as the sheath 302, is not charge neutral. The sheath 302 has a space charge density distribution giving rise to a non-zero electric field (Eₛₕ) extending for about a Debye Length beyond the neutral bulk second plasma 102. The higher mobility of electrons relative to the slower ions contributes to the sheath 302 being negatively charged. In accordance with the polarity of the charge, the electric potential is reducing in the sheath 302 between the bulk second plasma 102 till it reaches the ground potential (zero volts) at the staggered bilayer conductive grid 350 (in FIG. 7A) or the conductive grid 360 (in FIG. 7B). Accordingly, the plasma potential is positive with respect to the grid potential (Φₚ>0 V) and the direction of Eₛₕ is such that positively charged ions entering the sheath 302 would be pushed towards the conductive grid 350/360.

As illustrated in FIGS. 7A and 7B, positive ions 310 are electrically attracted towards the grounded grid (e.g., staggered bilayer conductive grid 350 (in FIG. 7A) or the conductive grid 360 (in FIG. 7B)) and the positive charge of the ions 310 may get neutralized by capturing free electrons supplied by the ground connection if they come in contact with the grid. The neutralization process converts a positive ion to a neutral radical. As illustrated in FIG. 7A, the neutralized ions bounce off the grid, and some may get deflected into the first portion 100 of the plasma processing chamber 150. The neutralized ions along with other free radicals diffusing from the second plasma 102 continue to diffuse towards the substrate 200 placed in the substrate holder 140 inside the second portion 130, as illustrated in FIGS. 7A and 7B.

The design of the staggered bilayer conductive grid 350 in FIG. 7A reduces the probability of allowing a positive ion to pass through from the second region to the first region. In further embodiments, although illustrated as a bilayer in FIG. 7A, the staggered bilayer conductive grid 350 may comprise more than two layers. A positive ion may occasionally pass through a single layer grid, such as the conductive grid 360, as shown in the example illustrated in FIG. 7B. However, the conductive grid 360, in FIG. 7B, uses a high-aspect-ratio grid (e.g, thicker along the direction facing the substrate 200 than the associated opening) to enhance the probability of a positive ion to collide with a conductive surface and get neutralized.

FIG. 8 illustrates a system-level implementation of dynamic reconfiguration of the plasma processing apparatus as discussed in various embodiments.

The block diagram in FIG. 8 illustrates a system-level implementation of dynamic reconfiguration of the plasma processing apparatus 1000/2000 that may be used to switch between multiple plasma process steps in one processing cycle, as in the example processes described below.

In FIG. 8, ground, dc bias, RF bias, dc bias, and high frequency RF taps from the plasma processing apparatus 1000 are being connected to RF power sources and ground connections 700 via a switching network 710. The switching network 710 may comprise solid-state switches and/or mechanical switches operated, for example, by servo motors. The state of the switching network 710 may be reconfigured dynamically by a programmable electronic controller 720 to implement a desired sequence of configurations.

FIGS. 9 and 10 are schematic illustrations of examples of semiconductor processes using embodiments of the plasma system described above.

A fabrication process flow for manufacturing semiconductor devices utilizes plasma processing for a number of process steps, comprising etching and deposition of thin films. For example, plasma-assisted processes may be used to create sacrificial gate structures by anisotropic etching of amorphous silicon using RIE, fill high-aspect-ratio shallow trench isolation (STI) trenches by deposition of silicon oxide using HDP-CVD, form a conformal thin metal liner (e.g., a Ta or TaN liner) at a low deposition temperature using PEALD, deposit an intermetal dielectric (IMD) layer of low-k silicon oxide (e.g., fluorosilicate glass (FSG)) using plasma-enhanced chemical vapor deposition (PECVD), or etch a deep through-silicon via (TSV).

Several plasma processing techniques such as RIE, physical vapor deposition (PVD), and sputter etch exploit the ability to accelerate charged particles by applying an electric bias. For example, in an RIE process, reactant ions may be accelerated towards the substrate and remove material anisotropically (preferentially in the vertical direction) as the reactants collide with the surface with enhanced momentum in the normal direction. Because of its anisotropic nature, RIE is found to be suitable to form structural features such as sidewall spacers and trenches. Another example of plasma processing utilizing electrically accelerated ions is sputtering. For example, during PVD, accelerated ions may be directed to impinge upon a target source of material (e.g., Al) and sputter atoms off the target to deposit on the surface of a substrate. The ions being charged particles, it is expected that such plasma processes would prefer to use plasma with a relatively high density of the reactant ions. Other processes such as conformal deposition using PECVD or plasma-assisted isotropic dry etch used to perform, for example, a chamber clean, or form a lateral undercut, the chemical component is dominant and isotropic. It is expected that such plasma processes would prefer to use plasma with a relatively high density of the highly reactive radicals. In some other applications, the physical and chemical components of the process are adjusted to achieve the requisite structure. For example, an HDP-CVD technique used for void-free filling of wide and narrow trenches in a substrate may be a simultaneous deposition/etch process. Typically, the HDP-CVD process would include a sputter etch component needed to retain the top openings of the high aspect ratio narrow trenches as the bottom of the wide trenches are filled.

In many such plasma processes, it may be advantageous to change the ion-to-radical ratio. For example, cyclic-etch and cyclic-deposition processes may alternate between a plasma etch and a plasma deposition cycle. The etch cycles and the deposition cycles may use different ion-to-radical ratio, the etch steps may prefer more ions while the deposition steps may prefer more radicals. Embodiments of plasma processing apparatus and methods, described in further detail below, may be used to implement processes with easily adjustable ion-to-radical ratio.

FIG. 9A illustrates one cycle of a semiconductor process comprising a first process step 400 followed by a second process step 450. For example, the semiconductor process may be a cyclic-etch process wherein the first process step 400 may be an RIE step and the second process step may be a passivating liner deposition step using PECVD. The plasma processing apparatus 1000/2000 may be configured to use only the inductively-coupled plasma 132 or the capacitively-coupled plasma 135 to provide the ions needed to implement the first process step 400 and then switch to a configuration wherein only the second plasma 102 is used to implement the second process step 450.

In this cyclic-etch example, and also for cyclic-deposition processes where the processing alternates between a deposition and an etch step, it is advantageous that the switching between alternate configurations may be done quickly using electronic controllers. In some other applications such as periodic plasma etch for chamber cleaning or periodic plasma deposition for chamber conditioning, the rapid switching feature may not be necessary.

FIG. 9B illustrates yet another example of a semiconductor process where it may be advantageous to use the embodiments described in this disclosure. One cycle of the process comprises one reaction cycle of a PEALE process 500 followed by one reaction cycle of a PEALD process 600. Each reaction cycle of a PEALE or PEALD comprises two self-limiting half-reaction pulses using different precursor gases.

In FIG. 9B, the PEALE process 500 comprises a pair of half-reaction pulses 510 and 520 and the PEALD process 600 comprises a pair of half-reaction pulses 610 and 620. The PEALE half-reaction pulses 510 and 520 may be implemented by configuring plasma processing apparatus 1000/2000 to use only the inductively-coupled plasma 132 or the capacitively-coupled plasma 135 to implement the etch process 500, while the PEALD half-reaction pulses 610 and 620 may be implemented by configuring plasma processing apparatus 1000/2000 to use only the second plasma 102 to implement the deposition process 600. Although not shown, every reaction pulse may be followed by a purge pulse.

Accordingly, various embodiments described in this disclosure provide plasma processing apparatus, wherein the ion-to-radical ratio of the flux of ions to the flux of radicals at the surface of a substrate may be adjusted over a wide range by altering the electrical configuration of the plasma equipment.

As discussed in greater detail above, ions and radicals are utilized in different ways during a plasma processing step because of the differences in their chemical and electrical properties. Accordingly, plasma processing apparatus, where the ion-to-radical ratio is electrically adjustable over a wide range, provides the advantage of greater flexibility in process design.

Example embodiments of the invention are summarized here. Other embodiments can also be understood from the entirety of the specification as well as the claims filed herein.

### EXAMPLE 1

A plasma processing apparatus includes a plasma processing chamber comprising a first portion and a second portion. The first portion comprises sidewalls and a top cover comprising a through hole. The second portion is coupled to the first portion via the through hole. A substrate holder is disposed in the first portion of the plasma processing chamber. A first coil is disposed over the first portion and a second coil is disposed over the first portion and around the second portion.

### EXAMPLE 2

The apparatus of example 1, where the first coil is a planar coil, where the second coil is a vertical coil.

### EXAMPLE 3

The apparatus of one of examples 1, where the first coil is a partial conical helical coil, where the second coil is a vertical coil.

### EXAMPLE 4

The apparatus of one of examples 1 to 3, further including: a grid disposed between the first portion and the second portion, where the first portion is fluidly coupled to the second portion through the grid.

### EXAMPLE 5

The apparatus of one of examples 1 to 4, where the first coil and the second coil are a monolithic wire.

### EXAMPLE 6

The apparatus of one of examples 1 to 4, where the first coil and the second coil are bonded together as an integrated structure.

### EXAMPLE 7

The apparatus of one of examples 1 to 6, further including: a plurality of first electrical contact taps for coupling the integrated structure to a reference potential node; and a plurality of second electrical contact taps for coupling the integrated structure to a power source.

### EXAMPLE 8

The apparatus of one of examples 1 to 7, where the first coil is part of a first helical resonator, and the second coil is part of a second helical resonator.

### EXAMPLE 9

A plasma processing apparatus comprises a plasma processing chamber that comprises a first portion and a second portion, which are formed as a monolithic structure. The first portion is configured to sustain a first plasma, which is configured to provides a first ion flux and a first radical flux at a substrate. The second portion is configured to sustain a second plasma, which is configured to provide a second ion flux and a second radical flux at the substrate. A first ratio between the first ion flux and the first radical flux is greater than a second ratio between the second ion flux and the second radical flux. A substrate holder is disposed in the first portion of the plasma processing chamber.

### EXAMPLE 10

The apparatus of example 9, further including: a grid disposed between the first portion and the second portion, the grid configured to neutralize ions incident on the grid.

### EXAMPLE 11

The apparatus of one of examples 9 or 10, further including: a first coil disposed over the first portion of the plasma processing chamber, the first coil coupled between a first power source and a reference potential node; and a second coil disposed around the second portion of the plasma processing chamber, the second coil coupled between a second power source and the reference potential node.

### EXAMPLE 12

The apparatus of one of examples 9 to 11, further including: an integrated structure including the first coil and the second coil.

### EXAMPLE 13

The apparatus of one of examples 9 to 12, further including: a plurality of first electrical contact taps for coupling the integrated structure to a reference potential node; and a plurality of second electrical contact taps for coupling the integrated structure to a power source.

### EXAMPLE 14

The apparatus of one of examples 9 to 13, where the first coil is part of a first helical resonator, and the second coil is part of a second helical resonator.

### EXAMPLE 15

The apparatus of one of examples 9 to 14, where the first coil is a planar coil, where the second coil is a vertical coil.

### EXAMPLE 16

The apparatus of one of examples 9 to 14, where the first coil is a partial conical helical coil, where the second coil is a vertical coil.

### EXAMPLE 17

A method of plasma processing comprises sustaining a first plasma within a first portion of a plasma processing chamber, sustaining a second plasma within a second portion of a plasma processing chamber, and processing a substrate with the first plasma and the second plasma. The first plasma provides a first ion flux and a first radical flux at the substrate, while the second plasma provides a second ion flux and a second radical flux at the substrate. A first ratio between the first ion flux and the first radical flux is greater than a second ratio between the second ion flux and the second radical flux.

### EXAMPLE 18

The method of example 17, where processing the substrate includes: exposing the substrate to the first plasma before sustaining the second plasma.

### EXAMPLE 19

The method of one of examples 17 or 18, where processing the substrate includes: switching off the first plasma; and exposing the substrate to the second plasma after switching off the first plasma.

### EXAMPLE 20

The method of one of examples 17 to 19, where processing the substrate includes: using a grid to neutralize the ions from the second plasma; and exposing the substrate to radicals and ions transmitted from the second plasma through the grid.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A plasma processing apparatus comprising:
a plasma processing chamber comprising a first portion and a second portion, the first portion comprising sidewalls and a top cover comprising a through hole, the second portion being coupled to the first portion via the through hole;
a substrate holder disposed in the first portion of the plasma processing chamber;
a first coil disposed over the first portion; and
a second coil being disposed over the first portion and around the second portion.

2. The apparatus of claim 1, wherein the first coil is a planar coil, wherein the second coil is a vertical coil.

3. The apparatus of claim 1, wherein the first coil is a partial conical helical coil, wherein the second coil is a vertical coil.

4. The apparatus of claim 1, further comprising:
a grid disposed between the first portion and the second portion, wherein the first portion is fluidly coupled to the second portion through the grid.

5. The apparatus of claim 1, wherein the first coil and the second coil are a monolithic wire.

6. The apparatus of claim 1, wherein the first coil and the second coil are bonded together as an integrated structure.

7. The apparatus of claim 6, further comprising:
a plurality of first electrical contact taps for coupling the integrated structure to a reference potential node; and
a plurality of second electrical contact taps for coupling the integrated structure to a power source.

8. The apparatus of claim 1, wherein the first coil is part of a first helical resonator, and the second coil is part of a second helical resonator.

9. A plasma processing apparatus comprising:
a plasma processing chamber comprising a first portion and a second portion, the first portion being configured to sustain a first plasma, the first plasma being configured to provide a first ion flux and a first radical flux at a substrate, the second portion being configured to sustain a second plasma, the second plasma being configured to provide a second ion flux and a second radical flux at the substrate, wherein a first ratio between the first ion flux and the first radical flux is greater than a second ratio between the second ion flux and the second radical flux, the first portion and the second portion being formed as a monolithic structure; and
a substrate holder disposed in the first portion of the plasma processing chamber.

10. The apparatus of claim 9, further comprising:
a grid disposed between the first portion and the second portion, the grid configured to neutralize ions incident on the grid.

11. The apparatus of claim 9, further comprising:
a first coil disposed over the first portion of the plasma processing chamber, the first coil coupled between a first power source and a reference potential node; and
a second coil disposed around the second portion of the plasma processing chamber, the second coil coupled between a second power source and the reference potential node.

12. The apparatus of claim 11, further comprising:
an integrated structure comprising the first coil and the second coil.

13. The apparatus of claim 12, further comprising:
a plurality of first electrical contact taps for coupling the integrated structure to a reference potential node; and
a plurality of second electrical contact taps for coupling the integrated structure to a power source.

14. The apparatus of claim 11, wherein the first coil is part of a first helical resonator, and the second coil is part of a second helical resonator.

15. The apparatus of claim 11, wherein the first coil is a planar coil, wherein the second coil is a vertical coil.

16. The apparatus of claim 11, wherein the first coil is a partial conical helical coil, wherein the second coil is a vertical coil.

17. A method of plasma processing, the method comprising:
sustaining a first plasma within a first portion of a plasma processing chamber;
sustaining a second plasma within a second portion of a plasma processing chamber; and
processing a substrate with the first plasma and the second plasma, the first plasma providing a first ion flux and a first radical flux at the substrate, the second plasma providing a second ion flux and a second radical flux at the substrate, wherein a first ratio between the first ion flux and the first radical flux is greater than a second ratio between the second ion flux and the second radical flux.

18. The method of claim 17, wherein processing the substrate comprises:
exposing the substrate to the first plasma before sustaining the second plasma.

19. The method of claim 17, wherein processing the substrate comprises:
switching off the first plasma; and
exposing the substrate to the second plasma after switching off the first plasma.

20. The method of claim 17, wherein processing the substrate comprises:
using a grid to neutralize the ions from the second plasma; and
exposing the substrate to radicals and ions transmitted from the second plasma through the grid.
